(19) United States
(12) Patent Application Publication
(10) Pub. No.: US 2015/0303328 A1
(43) Pub. Date: Oct. 22, 2015

(54) METHOD OF FORMING CIGS ABSORBER LAYER FOR SOLAR CELL AND CIGS SOLAR CELL

(71) Applicant: KOREA INSTITUTE OF ENERGY RESEARCH, Daejeon (KR)

(72) Inventors: Jae Ho Yun, Daejeon (KR); Jihye Gwak, Daejeon (KR); SeJin Ahn, Daejeon (KR); Kyung Hoon Yoon, Daejeon (KR); Kee Shik Shin, Daejeon (KR); SeoungKyu Ahn, Daejeon (KR); Ara Cho, Seoul (KR); Sang Hyun Park, Daejeon (KR); Hisun Park, Gyeonggi-do (KR); Sung Woo Choi, Seoul (KR)

(21) Appl. No.: 14/364,886

(22) PCT Filed: Jul. 10, 2013
(86) PCT No.: PCT/KR2013/006117

§ 371 Date: Jun. 12, 2014

(30) Foreign Application Priority Data
Jul. 13, 2012 (KR) 10-2012-0076562

(51) Int. Cl. H01L 31/032; H01L 31/18

(52) U.S. Cl. CPC H01L 31/0322; H01L 31/18

(57) ABSTRACT

A method of forming a CIGS absorber layer using a three-stage co-evaporation process, which can improve the efficiency of a solar cell in the case where Na concentration of a substrate is low and thus the depletion layer of the CIGS absorber layer is thick. The method includes a first stage of co-evaporating In, Ga and Se to deposit them; a second stage of co-evaporating Cu and Se to deposit them; and a third stage of co-evaporating In, Ga and Se to deposit them, wherein Ga supply through evaporation in the first stage is greater than Ga supply through evaporation in the third stage.

### TECHNICAL FIELD

The present invention relates to a method of forming a CIGS absorber layer for a solar cell and a CIGS solar cell, and more particularly, to a method of forming a CIGS absorber layer, which can improve the efficiency of a solar cell in the case where the concentration of alkali of a substrate is low and thus the depletion layer of the CIGS absorber layer is thick.

### BACKGROUND ART

Recently, the need to develop next-generation clean energy is increasing in importance due to serious environmental pollution problems and the exhaustion of fossil energy. Especially, solar cells, which are used to directly convert solar energy into electric energy, are expected to become an energy source able to solve the energy problems of the future because they generate less pollution, utilize unlimited solar resources and have a semi-permanent lifespan.

Solar cells are classified into a variety of types depending on the material for an absorber layer. Currently, the most commonly used is a Si solar cell using Si. However, as the price of Si has drastically increased attributable to the recent Si supply shortage, thin-film solar cells are receiving attention. Thin-film solar cells are thin and enable smaller amounts of materials to be consumed, and are also light and have a wider range of utilization. Thorough research is ongoing into using amorphous Si and CdTe, CIS (CuInSeJ or CIGS (CuIn₁₋ₓGaₓSe₂) as materials of such thin-film solar cells.

A CIGS thin film has a high absorption coefficient of 1×10⁵ cm⁻¹, and the band gap thereof may be adjusted in a wide range of 1˜2.7 eV depending on the kind of additive. Furthermore, because such a thin film is very thermally stable, it exhibits almost uniform efficiency even when exposed to solar light for a long period of time, and also has high moisture resistance. This CIGS thin film is formed by way of diverse methods, and particularly, the solar cell using a CIGS thin film formed by a co-evaporation process based on PVD has the highest efficiency. Examples of the co-evaporation process may include one-stage co-evaporation, two-stage co-evaporation, and three-stage co-evaporation. Among these, the use of a three-stage co-evaporation process results in the highest efficiency.

FIG. 4 illustrates a process of forming a CIGS absorber layer using three-stage co-evaporation.

Specifically in the first stage, In, Ga and Se are evaporated at a substrate temperature of about 450° C. so as to deposit (In,Ga)₂Se₃. In the second stage, while the substrate temperature is increased to about 700° C., Cu and Se are supplied so as to make a Cu-rich state. Finally in the third stage, while the substrate temperature is maintained, In, Ga and Se are evaporated, thus forming a Cu-deficient CIGS thin film.

The CIGS thin film thus formed is grown to an alpha phase thanks to formation of Cu₂₋ₓSe at the surface by the Cu-rich state in the second stage. Hence, while β-CIGS and γ-CIGS formed in the first stage are phase transformed into α-CIGS in the second stage, coarse crystal grains are formed.

Also, the CIGS thin film has band gap energy varying depending on the Ga/(In+Ga) ratio, and three-stage co-evaporation may increase the efficiency of the CIGS thin-film solar cell by way of a double grading structure in which the band gap energy is high at the back contact side and the front side and is low at the center, by decreasing the Ga/(In+Ga) ratio in the second stage.

FIG. 5 schematically illustrates the case where a double band gap slope is formed in the CIGS thin film (“High efficiency graded bandgap thin-film polycrystalline Cu(In,Ga)Se₂-based solar cells”, Solar Energy Materials and Solar Cells 41/42 (1996) 231-246).

As mentioned above, when the band gap of the front side of the CIGS thin film is higher than that of the center thereof, open-circuit voltage may increase and recombination may be reduced. When the band gap of the back side of the CIGS thin film is higher than that of the center thereof, electron mobility may increase.

Meanwhile, a CIGS solar cell is typically manufactured on a sodalime glass substrate. This is because the efficiency of the CIGS solar cell is increased by various functions of Na contained in the sodalime glass substrate. However, the sodalime glass substrate has a low melting point, and thus imposes limitations on manufacturing the CIGS solar cell. Furthermore, the CIGS solar cell suffers from not using a flexible substrate made of a metal or polymer. To solve such problems, a variety of methods, including forced implantation of Na, etc. are under study, but the demand for techniques for increasing the efficiency of solar cells without the addition of Na is increasing.

Therefore, techniques for increasing the efficiency of solar cells by improving the process of forming the CIGS thin film without the use of a sodalime glass substrate and Na are receiving attention.

### CITATION LIST

“High efficiency graded bandgap thin-film polycrystalline Cu(In,Ga)Se2-based solar cells”, Solar Energy Materials and Solar Cells 41/42 (1996) 231-246

### DISCLOSURE

### Technical Problem

Accordingly, the present invention has been made keeping in mind the above problems encountered in the related art, and an object of the present invention is to provide a method of forming a CIGS absorber layer, in which the depth of the depletion region thereof may increase by use of a substrate having low alkali concentration, thereby improving the efficiency of a CIGS solar cell including such a CIGS absorber layer.

### Technical Solution

In order to accomplish the above object, an aspect of the present invention provides a method of forming a CIGS absorber layer for a solar cell using a three-stage co-evaporation process, comprising a first stage of co-evaporating In, Ga and Se to deposit them; a second stage of co-evaporating Cu and Se to deposit them; and a third stage of co-evaporating In, Ga and Se to deposit them, wherein Ga supply through evaporation in the first stage is greater than Ga supply through evaporation in the third stage.

Conventionally, many attempts have been made to improve the efficiency of CIGS solar cells manufactured using a sodalime glass substrate by adjusting the Ga supply proportion upon applying a three-stage co-evaporation process. However, because there is no great effect due to changes in the Ga supply in the first stage, Ga is typically supplied in the same amount in the first and third stages. The present inventors have devised a method of improving solar cell efficiency by increasing the Ga proportion in the first stage of the co-evaporation process.

As such, the depth of a depletion region formed in the CIGS absorber layer is preferably 400 nm or more. In the present invention, cell efficiency may be further improved upon formation of a CIGS absorber layer having a deeper depletion layer compared to a CIGS absorber layer formed on a typical sodalime glass substrate.

The CIGS absorber layer having a deeper depletion layer is formed when using a substrate having low Na concentration, and such a substrate may be a sodalime glass substrate having an alkali concentration of 8 wt % or less in glass or a substrate made of a material other than the sodalime glass substrate.

In the first and third stages, the amount of evaporated In is 3 Å/s, and the amount of evaporated Ga in the first stage is 1.6 Å/s or more, and the amount of evaporated Ga in the third stage is 1.5 Å/s.

Also, the first stage is preferably performed in the substrate temperature range of 300-450° C., and the second and third stages are preferably carried out in the substrate temperature range of 480-550° C.

Another aspect of the present invention provides a CIGS solar cell, comprising a CIGS absorber layer formed using any one among the above methods.

A further aspect of the present invention provides a CIGS solar cell, comprising a substrate; an electrode layer formed on the substrate; and a CIGS absorber layer formed on the electrode layer, wherein the Ga/(In+Ga) ratio is 0.45 or more at the interface between the electrode layer and the CIGS absorber layer.

The present inventors have devised a CIGS solar cell having improved efficiency by use of an absorber layer having an increased Ga/(In+Ga) ratio at the back contact interface by increasing the Ga proportion in the first stage of the co-evaporation process.

As such, the depth of the depletion layer region formed in the CIGS absorber layer is preferably 400 nm or more. To this end, a sodalime glass substrate having an alkali concentration of 8 wt % or less in glass or a substrate made of a material other than the sodalime glass substrate may be used.

### Advantageous Effects

According to the present invention, in the course of forming a CIGS absorber layer using a three-stage co-evaporation process, the amount of evaporated Ga in the first stage is increased, thereby increasing the efficiency of a CIGS solar cell having a deep depletion layer on a substrate having low Na concentration.

Also, according to the present invention, the CIGS solar cell can be manufactured using a sodalime glass substrate having low Na concentration or a substrate made of a material other than the sodalime glass substrate, thus making it possible to manufacture CIGS solar cells using a substrate having excellent thermal stability and a substrate having various properties.

### DESCRIPTION OF DRAWINGS

FIG. 1 is a graph illustrating the Ga/(In+Ga) ratio distribution of a CIGS absorber layer depending on changes in the amount of evaporated Ga in the first stage according to the present embodiment;

FIG. 2 is a schematic view illustrating the structure of a CIGS solar cell manufactured according to the present embodiment;

FIG. 3 is a graph illustrating the efficiency of the solar cell including the CIGS absorber layer according to the present embodiment;

FIG. 4 is a view illustrating a process of forming a CIGS absorber layer using a three-stage co-evaporation process; and

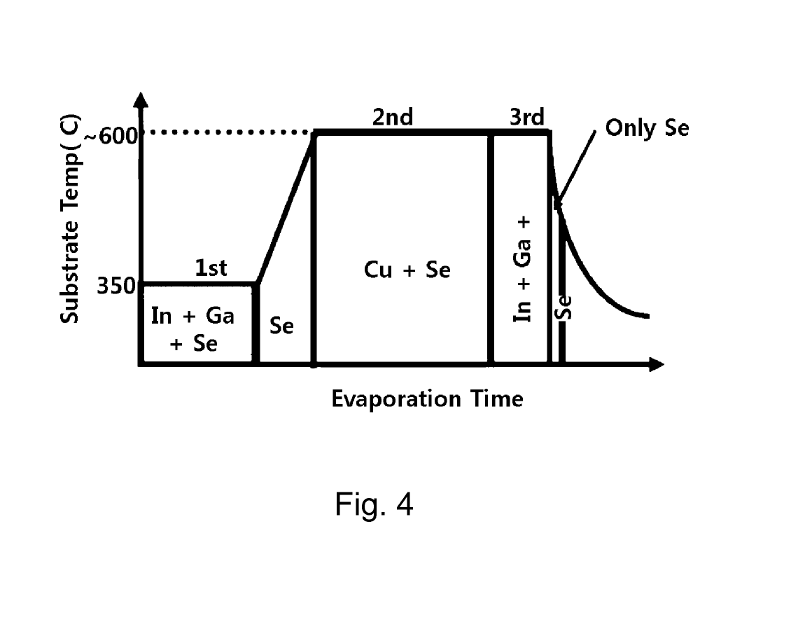

FIG. 5 is a schematic view illustrating the case where a double band gap slope is formed in a CIGS thin film.

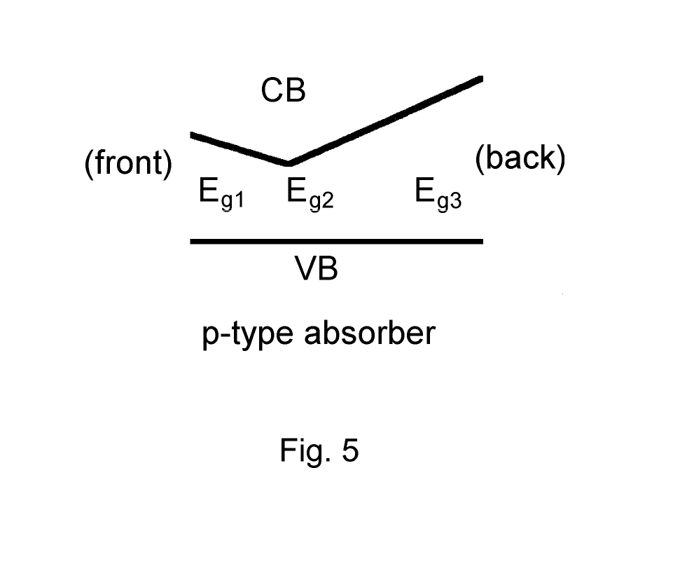

### MODE FOR INVENTION

Hereinafter, a detailed description will be given of embodiments of the present invention with reference to the appended drawings.

Specifically, a Mo back contact is deposited to a thickness of about 1 μm using DC sputtering on a sodalime glass substrate having an alkali concentration of 8 wt %. The sodalime glass substrate used in the present embodiment has a comparatively lower alkali concentration than 12 wt % which is the alkali concentration of a typical sodalime glass substrate for a CIGS solar cell.

Subsequently, a CIGS absorber layer is formed using a three-stage co-evaporation process.

The first stage is evaporating In, Ga and Se to deposit them while maintaining the substrate temperature in the range of 300-450° C., and the second stage is depositing Cu and Se while maintaining the substrate temperature in the range of 480-550° C. The third stage is evaporating In, Ga and Se to deposit them while maintaining the substrate temperature in the range of 480-550° C. This process is the same as in a typical three-stage co-evaporation process for forming a CIGS absorber layer, with the exception that the amount of evaporated Ga in the first stage is adjusted in the present embodiment.

Specifically, in the first stage, co-evaporation is performed in such a manner that the amount of evaporated In is fixed to 3 Å/s but the amount of evaporated Ga is changed to 1.5, 1.6, 1.7 and 1.8 Å/s. In order to exclude changes in deposition thickness in proportion to an increase in the amount of evaporated Ga, the deposition thickness in the first stage is uniformly set to 1 μm.

Whereas in the third stage, co-evaporation is performed in such a manner that the amounts of evaporated In and Ga are fixed to 3 Å/s and 1.5 Å/s, respectively. On the other hand, the amount of evaporated Se in the entire process is 3 Å/s, and the amount of evaporated Cu in the second stage is 2.5 Ås.

In the CIGS thin film, the Ga/(In+Ga) ratio has an influence on the preferred orientation of the CIGS thin film. Because the CIGS thin film exhibits the preferred orientation of (220)/(204) at the Ga/(In+Ga) ratio closer to 0.3-0.35, the evaporation of Ga and In is adjusted to meet this ratio.

Because a double grading structure is formed by a three-stage co-evaporation process, the Ga/(In+Ga) ratio typically approximates to 0.4 at the interface between the back contact and the CIGS absorber layer.

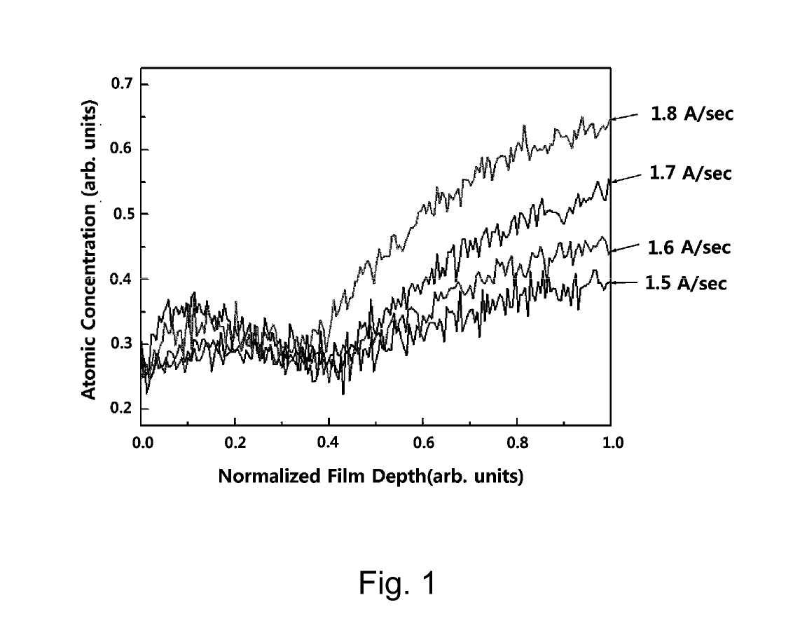

FIG. 1 is a graph illustrating the Ga/(In+Ga) ratio distribution of the CIGS absorber layer formed while changing the amount of evaporated Ga in the first stage according to the present embodiment. In the graph, the left corresponds to the front side, and the right corresponds to the back contact side.

In the method of forming the CIGS absorber layer according to the present embodiment, the CIGS thin film is formed on the back contact, and thus the portion formed in the first stage is the right close to the back contact. As illustrated in this drawing, as the amount of evaporated Ga increases, the Ga/(In+Ga) ratio can be seen to increase at the interface between the CIGS absorber layer and the back contact.

The results are shown in Table 1 below.

TABLE 1

| | Amount | | | |
|---|---|---|---|---|
| | of evaporated Ga in 1^{st} stage | | | |
| | 1.5 Ås | 1.6 Å/s | 1.7 Å/s | 1.8 Å/s |
| Ga/(In + Ga) ratio at interface | 0.4 | 0.45 | 0.54 | 0.65 |
| between CIGS absorber layer and | | | | |
| back contact | | | | |

Meanwhile, the substrate used in the present embodiment has a lower alkali concentration than 12 wt % which is the alkali concentration of a typical sodalime glass substrate for a CIGS solar cell, and thus the melting point thereof is comparatively high, whereby a higher temperature may be applied in the course of formation of the CIGS solar cell.

The alkali concentration of the substrate may affect the depth of the depletion layer of the CIGS absorber layer. In the case of using a conventional sodalime glass substrate having an alkali concentration of about 12 wt % or more for a CIGS solar cell, the depletion layer of the CIGS absorber layer has a depth of 200-300 nm from the surface. However, when using a sodalime glass substrate having a comparatively low alkali concentration of 8 wt % or less according to the present embodiment, the depth of the depletion layer of the CIGS absorber layer falls in the range of 400-600 nm. In the case of using a substrate made of a metal or polymer having a lower alkali concentration, the depth of the depletion layer formed in the CIGS absorber layer may be further increased.

After formation of the CIGS absorber layer as above, a CIGS solar cell is finally manufactured, and measured for photoelectric conversion efficiency.

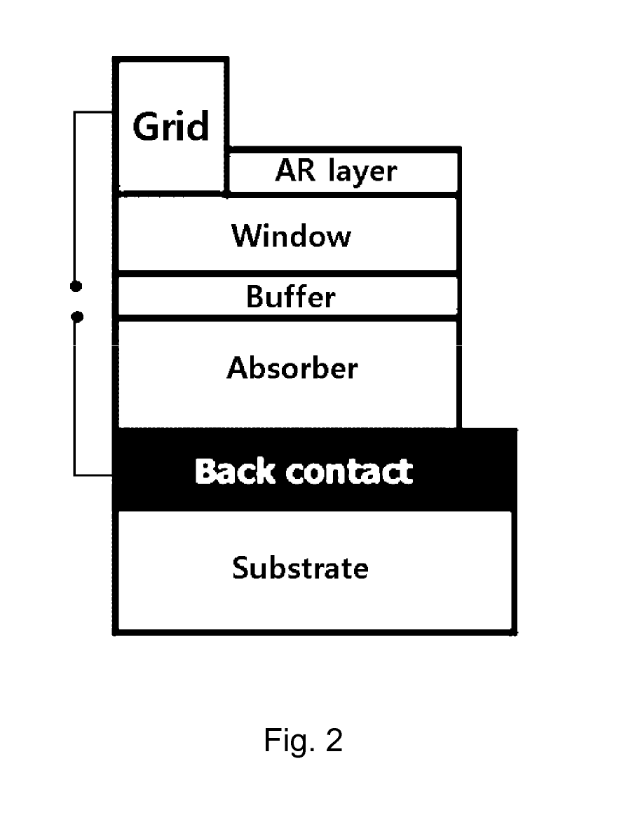

FIG. 2 schematically illustrates the structure of the CIGS solar cell manufactured according to the present embodiment. The CIGS solar cell according to the present embodiment has the same configuration as in a typical CIGS solar cell as illustrated in the drawing, with the exception of the Ga/(In+Ga) ratio at the interface between the CIGS absorber layer and the back contact. The substrate, the back contact and the absorber layer are as described above, and a buffer layer, a window layer, a front anti-reflective layer and a front contact are the same as in a typical configuration, and thus a detailed description thereof is omitted.

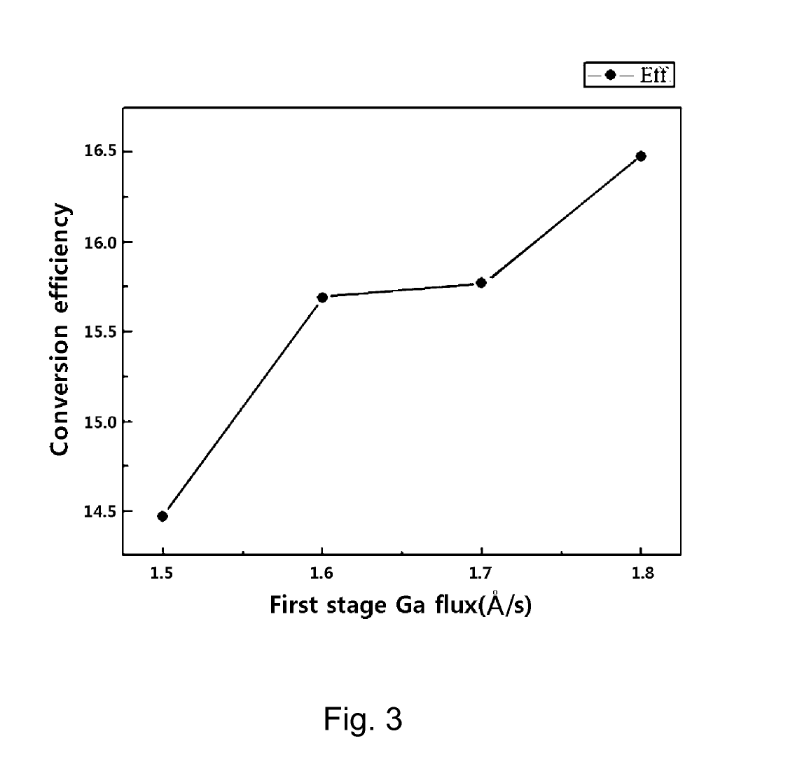

FIG. 3 is a graph illustrating the efficiency of the solar cell including the CIGS absorber layer formed according to the present embodiment.

As illustrated in this drawing, the efficiency of the solar cell may increase in proportion to an increase in the amount of evaporated Ga in the first stage. Accordingly, the CIGS absorber layer having a deeper depletion layer formed on the substrate having a lower Na concentration than that of a typical sodalime glass substrate causes the efficiency of the solar cell to increase in proportion to an increase in the Ga/(In+Ga) ratio at the interface with the back contact.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Therefore, the scope of the present invention should be understood not by specific embodiments but by claims, and all technical ideas equivalent thereto will be understood to be incorporated into the scope of the present invention.

1. A method of forming a CIGS absorber layer for a solar cell using a three-stage co-evaporation process, comprising:
a first stage of co-evaporating In, Ga and Se to deposit them;
a second stage of co-evaporating Cu and Se to deposit them; and
a third stage of co-evaporating In, Ga and Se to deposit them,
wherein Ga supply through evaporation in the first stage is greater than Ga supply through evaporation in the third stage.

2. The method of claim 1, wherein a depth of a depletion layer region formed in the CIGS absorber layer is 400 nm or more.

3. The method of claim 2, wherein a substrate on which the GIGS absorber layer is formed comprises a material other than a sodalime glass substrate.

4. The method of claim 2, wherein a substrate on which the GIGS absorber layer is formed is a sodalime glass substrate having an alkali concentration of 8 wt % or less.

5. The method of claim 1, wherein an amount of In evaporated in the first stage and the third stage is 3 Ås, an amount of Ga evaporated in the first stage is 1.6 Å/s or more, and an amount of Ga evaporated in the third stage is 1.5 Å/s.

6. The method of claim 5, wherein the first stage is performed in a substrate temperature range of 300° C.-450° C., and the second stage and the third stage are performed in a substrate temperature range of 480° C.-550° C.

7. A CIGS solar cell, comprising:
a substrate;
an electrode layer formed on the substrate; and
a CIGS absorber layer formed on the electrode layer,
wherein a Ga/(In+Ga) ratio at an interface between the electrode layer and the CIGS absorber layer is 0.45 or more.

8. The CIGS solar cell of claim 7, wherein a depth of a depletion layer formed in the CIGS absorber layer is 400 nm or more.

9. The CIGS solar cell of claim 8, wherein the substrate comprises a material other than a sodalime glass substrate.

10. The CIGS solar cell of claim 8, wherein the substrate is a sodalime glass substrate having an alkali concentration of 8 wt % or less.
